(19) United States
(12) Patent Application Publication
(10) Pub. No.: US 2010/0140656 A1
(43) Pub. Date: Jun. 10, 2010

(54) Semiconductor Light-Emitting Device

(75) Inventors: Chang Tae Kim, Seongnam-si (KR); Gi Yeon NAM, Seognam-si (KR); Tae Hee LEE, Yesan-gun (KR)

Correspondence Address: HARNESS, DICKEY, & PIERCE, P.L.C, 7700 Bonhomme, Suite 400, ST. LOUIS, MO, 63105, US

(73) Assignee: EPIVALLEY CO., LTD., Gumi-city (KR)

(21) Appl. No.: 12/647,860

(22) Filed: Dec. 28, 2009

Related U.S. Application Data
(63) Continuation of application No. PCT/KR2009/007236, filed on Dec. 4, 2009.

(30) Foreign Application Priority Data
Dec. 4, 2008 (KR) 10-2008-0122467

(51) Int. Cl. H01L 33/00

(52) U.S. Cl. 257/99; 257/E33.062

(57) ABSTRACT

The present disclosure relates to a semiconductor light-emitting device generating light by recombination of electrons and holes. The semiconductor light-emitting device includes: a first bonding electrode and a second bonding electrode supplying the current for the recombination of the electrons and holes; a first branch electrode and a second branch electrode extended from the first bonding electrode; and a third branch electrode extended from the second bonding electrode, located between the first branch electrode and the second branch electrode, and having a first interval from the first branch electrode and a second interval smaller than the first interval from the second branch electrode. The second branch electrode is located farther from the center of the light-emitting device than the first branch electrode, and the second branch electrode is located farther from the center of the light-emitting device than the third branch electrode.

### CROSS-REFERENCE TO RELATED APPLICATIONS

This application is a continuation of PCT Application No. PCT/KR2009/007236 filed on Dec. 4, 2009, which claims the benefit and priority to Korean Patent Application No. 10-2008-0122467, filed Dec. 4, 2008. The entire disclosures of the applications identified in this paragraph are incorporated herein by reference.

### FIELD

The present disclosure relates generally to a semiconductor light-emitting device, and, more particularly, to a semiconductor light-emitting device having an electrode structure for current-spreading.

The III-nitride semiconductor light-emitting device means a light-emitting device, such as a light-emitting diode including a compound semiconductor layer composed of Al₍ₓ₎Ga_{(y)}In_{(1-x-y)}N (0≦x≦1, 0≦y≦1, 0≦x+y≦1), and may further include a material composed of other group elements, such as SiC, SiN, SiCN and CN, and a semiconductor layer made of such materials.

### BACKGROUND

This section provides background information related to the present disclosure which is not necessarily prior art.

FIG. 1 is a view of an example of a conventional III-nitride semiconductor light-emitting device. The III-nitride semiconductor light-emitting device includes a substrate 100, a buffer layer 200 grown on the substrate 100, an n-type III-nitride semiconductor layer 300 grown on the buffer layer 200, an active layer 400 grown on the n-type III-nitride semiconductor layer 300, a p-type III-nitride semiconductor layer 500 grown on the active layer 400, a p-side electrode 600 formed on the p-type III-nitride semiconductor layer 500, a p-side bonding pad 700 formed on the p-side electrode 600, an n-side electrode 800 formed on the n-type III-nitride semiconductor layer 300 exposed by mesa-etching the p-type III-nitride semiconductor layer 500 and the active layer 400, and an optional protection film 900.

In the case of the substrate 100, a GaN substrate can be used as a homo-substrate. A sapphire substrate, a SiC substrate or a Si substrate can be used as a hetero-substrate. However, any type of substrate that can have a nitride semiconductor layer grown thereon can be employed. In the case that the SiC substrate is used, the n-side electrode 800 can be formed on the surface of the SiC substrate.

The nitride semiconductor layers epitaxially grown on the substrate 100 are usually grown by metal organic chemical vapor deposition (MOCVD).

The buffer layer 200 serves to overcome differences in lattice constant and thermal expansion coefficient between the hetero-substrate 100 and the nitride semiconductor layers. U.S. Pat. No. 5,122,845 describes a technique of growing an AlN buffer layer with a thickness of 100 to 500 Å on a sapphire substrate at 380 to 800° C. In addition, U.S. Pat. No. 5,290,393 describes a technique of growing an Al₍ₓ₎Ga₍₁₋ₓ₎N (0≦x<1) buffer layer with a thickness of 10 to 5000 Å on a sapphire substrate at 200 to 900° C. Moreover, U.S. Publication No. 2006/154454 describes a technique of growing a SiC buffer layer (seed layer) at 600 to 990° C., and growing an In₍ₓ₎Ga₍₁₋ₓ₎N (0<x≦1) thereon. In particular, it is provided with an undoped GaN layer with a thickness of 1 micron to several microns (μm) on the AlN buffer layer, the Al₍ₓ₎Ga₍₁₋ₓ₎N (0≦x<1) buffer layer or the SiC/In₍ₓ₎Ga₍₁₋ₓ₎N (0<x≦1) layer.

In the n-type nitride semiconductor layer 300, at least the n-side electrode 800 formed region (n-type contact layer) is doped with a dopant. In some embodiments, the n-type contact layer is made of GaN and doped with Si. U.S. Pat. No. 5,733,796 describes a technique of doping an n-type contact layer at a target doping concentration by adjusting the mixture ratio of Si and other source materials.

The active layer 400 generates light quanta by recombination of electrons and holes. For example, the active layer 400 contains In₍ₓ₎Ga₍₁₋ₓ₎N (0<x≦1) and has a single layer or multi-quantum well layers.

The p-type III-nitride semiconductor layer 500 is doped with an appropriate dopant such as Mg, and has p-type conductivity by an activation process. U.S. Pat. No. 5,247,533 describes a technique of activating a p-type nitride semiconductor layer by electron beam irradiation. Moreover, U.S. Pat. No. 5,306,662 describes a technique of activating a p-type III-nitride semiconductor layer by annealing over 400° C. U.S. Publication No. 2006/157714 describes a technique of endowing a p-type nitride semiconductor layer with p-type conductivity without an activation process, by using ammonia and a hydrazine-based source material together as a nitrogen precursor for growing the p-type nitride semiconductor layer.

The p-side electrode 600 is provided to facilitate current supply to the p-type III-nitride semiconductor layer 500. U.S. Pat. No. 5,563,422 describes a technique associated with a light-transmitting electrode composed of Ni and Au formed over almost the entire surface of the p-type nitride semiconductor layer 500 and in ohmic-contact with the p-type III-nitride semiconductor layer 500. In addition, U.S. Pat. No. 6,515,306 describes a technique of forming an n-type superlattice layer on a p-type nitride semiconductor layer, and forming a light-transmitting electrode made of indium tin oxide (ITO) thereon.

The p-side electrode 600 can be formed so thick as to not transmit but rather to reflect light toward the substrate 100. This technique is called the flip chip technique. U.S. Pat. No. 6,194,743 describes a technique associated with an electrode structure including an Ag layer with a thickness over 20 nm, a diffusion barrier layer covering the Ag layer, a bonding layer containing Au and Al, and covering the diffusion barrier layer.

The p-side bonding pad 700 and the n-side electrode 800 are provided for current supply and external wire-bonding. U.S. Pat. No. 5,563,422 describes a technique of forming an n-side electrode with Ti and Al.

The optional protection film 900 can be made of SiO₂.

The n-type nitride semiconductor layer 300 or the p-type nitride semiconductor layer 500 can be constructed as a single layer or as plural layers. Vertical light-emitting devices are introduced by separating the substrate 100 from the nitride semiconductor layers using a laser technique or wet etching.

FIG. 2 is a view of an example of an electrode structure described in U.S. Pat. No. 5,563,422. A p-side bonding pad 700 and an n-side electrode 800 are positioned at opposite diagonal corner portions of a light-emitting device to improve current-spreading.

FIG. 3 is a view of an example of an electrode structure described in U.S. Pat. No. 6,307,218. With a large-area tendency of a light-emitting device, branch electrodes 910 are provided between p-side bonding pads 710 and n-side electrodes 810 at regular intervals to improve current-spreading.

However, the light-emitting device with the above-described electrode structure as described in, for example, U.S. Pat. No. 5,563,422 or U.S. Pat. No. 6,307,218 has the problem that the current is concentrated on regions R with a short distance between the p-side bonding pads 710 and the n-side electrodes 810.

If a bonding defect occurs on wires connected to the p-side bonding pads 710 or the n-side electrodes 810, then current-spreading of the light-emitting device is uneven.

FIG. 4 is a photograph of a semiconductor light-emitting device experiencing a wire-bonding defect. FIG. 4(a) is a photograph showing light emission of the light-emitting device with four wires normally bonded thereto, FIG. 4(b) is a photograph showing light emission of the light-emitting device with two wires separated therefrom and two wires bonded thereto in a diagonal direction. FIG. 4(c) is a photograph showing light emission of the light-emitting device with two wires separated therefrom and two wires bonded thereto in one direction. It can be seen in FIG. 4(c) that light is unevenly emitted because of the wire-bonding defect.

In various embodiments a light-emitting device in which two bonding pads are adhered to be located together has been introduced to solve the foregoing problem. Nevertheless, current concentration still occurs between bonding pads located on the opposite side.

### SUMMARY

This section provides a general summary of the disclosure, and is not a comprehensive disclosure of its full scope or all of its features.

There is provided a semiconductor light-emitting device generating light by recombination of electrons and holes, the semiconductor light-emitting device including: a first bonding electrode and a second bonding electrode supplying the current for the recombination of the electrons and holes; a first branch electrode and a second branch electrode extended from the first bonding electrode; and a third branch electrode extended from the second bonding electrode, located between the first branch electrode and the second branch electrode, and having a first interval from the first branch electrode and a second interval smaller than the first interval from the second branch electrode, wherein the second branch electrode is located farther from the center of the light-emitting device than the first branch electrode, and the second branch electrode is located farther from the center of the light-emitting device than the third branch electrode.

There is also provided herein a semiconductor light-emitting device generating light by recombination of electrons and holes, the semiconductor light-emitting device including: a first bonding electrode and a second bonding electrode supplying the current for the recombination of the electrons and holes, at least one of the first bonding electrode and the second bonding electrode having two bonding pads; a first branch electrode and a second branch electrode extended from the first bonding electrode; and a third branch electrode extended from the second bonding electrode, disposed between the first branch electrode and the second branch electrode, and having a first interval from the first branch electrode and a second interval smaller than the first interval from the second branch electrode.

According to a III-nitride semiconductor light-emitting device of the present disclosure, current concentration can be prevented.

In some embodiments, according to III-nitride semiconductor light emitting device of the present disclosure, current concentration is prevented in spite of a wire-bonding defect.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a view of an example of a conventional III-nitride semiconductor light-emitting device.

FIG. 2 is a view of an example of an electrode structure described in U.S. Pat. No. 5,563,422.

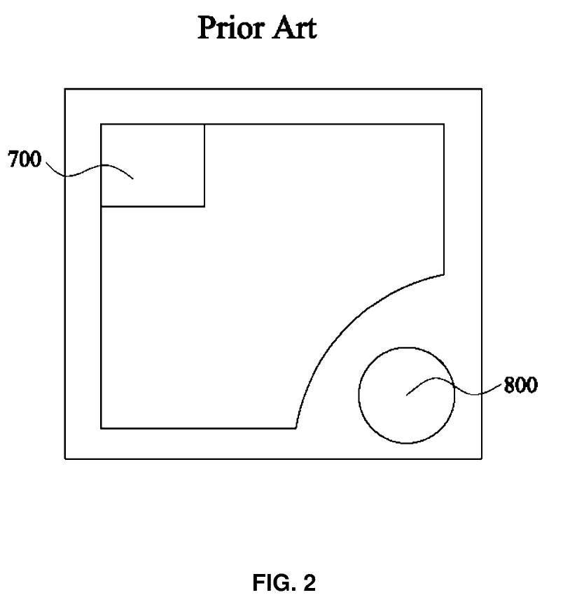

FIG. 3 is a view of an example of an electrode structure described in U.S. Pat. No. 6,307,218.

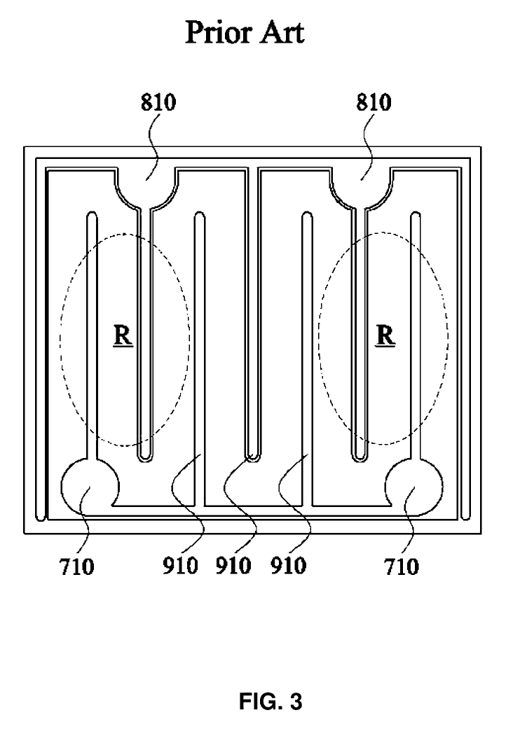

FIG. 4 is a photograph of a semiconductor light-emitting device experiencing a wire-bonding defect.

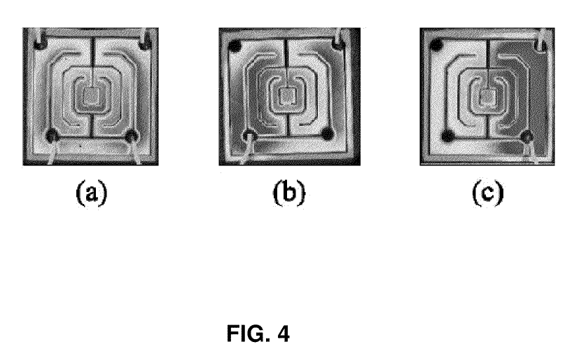

FIG. 5 is a view of an embodiment of an electrode structure of a semiconductor light-emitting device according to the present disclosure.

FIG. 6 is a view of an embodiment of a semiconductor light-emitting device according to the present disclosure.

Corresponding reference numerals indicate corresponding parts throughout the several views of the drawings.

### DETAILED DESCRIPTION

Hereinafter, the present disclosure will be described in detail with reference to the accompanying drawings.

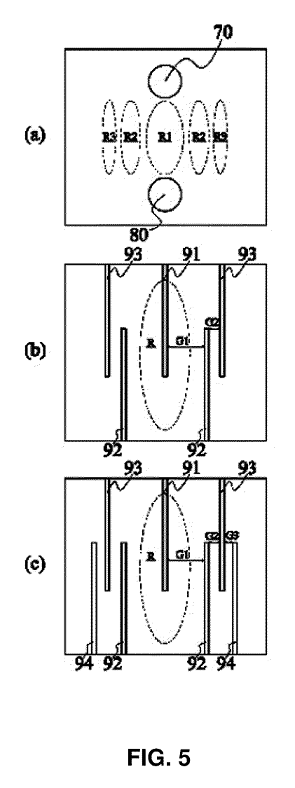

FIG. 5 is a view of an embodiment of an electrode structure of a light-emitting device according to the present disclosure. The electrode structure includes bonding pads 70 and 80 and branch electrodes 91, 92, 93, and 94.

The current is applied to the bonding pads 70 and 80. When the current is applied to the bonding pads 70 and 80, a region on which the current is not evenly spread but concentrated (hereinafter referred to as “concentration region R”) may be generated between the bonding pads 70 and 80. For example, the concentration region R is mostly located on a straight-line distance between the bonding pad 70 and the bonding pad 80. However, according to the present disclosure, the concentration region R is not limited to a region R1 located on the straight-line distance between the bonding pad 70 and the bonding pad 80, but also indicates a region on which the current is relatively concentrated as compared with the periphery; that is, the region R1 may be the concentration region R with respect to a region R2, and the region R2 may be the concentration region R with respect to a region R3 (see FIG. 5(a)). Therefore, the concentration region R may be formed in the region R1 when current distribution is relatively changed.

The branch electrode 91 is connected to the bonding pad 70 and located in the concentration region R. The branch electrode 92 is connected to the bonding pad 80 and is located at an interval G1 from the branch electrode 91. The branch electrode 93 is connected to the branch electrode 91 and located at an interval G2 from the branch electrode 92. For example, the interval G1 is larger than the interval G2 (see FIG. 5(b)). Therefore, the concentration region R can be reduced or removed. In some embodiments, the branch electrode 92 and the branch electrode 93 are sequentially arranged from the branch electrode 91 to be advantageous in reducing or removing the concentration region R.

Referring to FIG. 5(c), the branch electrode 94 is located at an interval G3 smaller than the interval G1 from the branch electrode 93. In some embodiments, the interval G3 is smaller than the interval G2. The reason for this is because the relationship between the interval G1 of the branch electrode 91 and the branch electrode 92 and the interval G2 of the branch electrode 92 and the branch electrode 93 can be applied to the interval G2 and the interval G3.

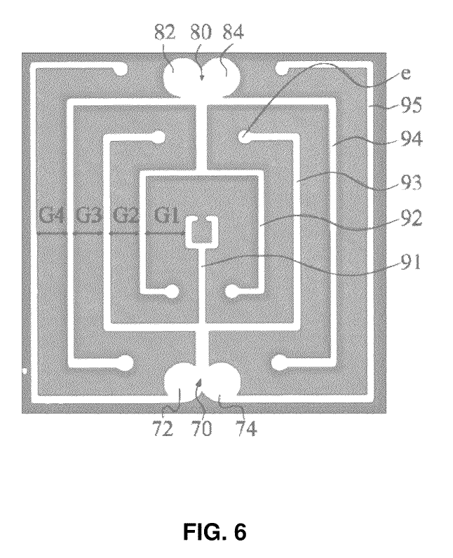

FIG. 6 is a view of an embodiment of a semiconductor light-emitting device according to the present disclosure. The light-emitting device includes bonding pads 70 and 80 and branch electrodes 91, 92, 93, 94, and 95. For example, it is assumed that the light-emitting device has a width and length of 1 mm.

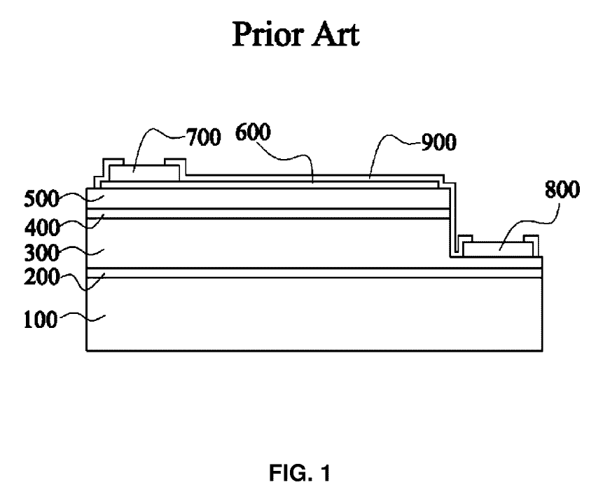

The bonding pad 70 and the bonding pad 80 supply the current so that an active layer (see FIG. 1) can emit light by recombination of electrons and holes. The bonding pad 70 and the bonding pad 80 are located between both sides of the light-emitting device. Two circular pads 72 and 74 are adhered to form the bonding pad 70, and the two circular pads 72 and 74 may be spaced apart from each other and connected to each other through the branch electrodes 91, 93, and 95 to form the bonding pad 70. In addition, the pads 72, 74, 82, and 84 may be formed in various shapes such as an ellipse, a polygon, etc.

The branch electrode 91 is extended from the bonding pad 70 toward the bonding pad 80, which means that the branch electrode 91 is located in a concentration region R, as explained with reference to FIG. 5.

The branch electrode 92 is located at an interval G1 from the branch electrode 91. For example, the branch electrode 92 is extended from the bonding pad 80 toward the bonding pad 70 and is split at both sides at an interval G1 of 128 μm from the branch electrode 91 so as to facilitate current-spreading. As a whole, the branch electrode 92 is bent and extended to surround the branch electrode 91.

The branch electrode 93 is located at an interval G2 smaller than the interval G1 from the branch electrode 92. For example, the branch electrode 93 is split at both sides of the branch electrode 91 at an interval G2 of 89 μm from the branch electrode 92 in order to facilitate current-spreading. As a whole, the branch electrode 93 is bent and extended to surround the branch electrode 92.

The branch electrode 94 is located at an interval G3 from the branch electrode 93. The interval G3 is smaller than the interval G1 and, in some embodiments, is smaller than the interval G2 as shown in FIG. 5. For example, the branch electrode 94 is split at both sides of the branch electrode 92 at an interval G3 of 80 μm from the branch electrode 93 so as to facilitate current-spreading. As a whole, the branch electrode 94 is bent and extended to surround the branch electrode 93.

The branch electrode 95 may be located at an interval G4 of, e.g., 89 μm from the branch electrode 94. The interval G4 may be larger or smaller than the interval G3 according to the degree of current concentration.

Annular extension portions e are formed at the branch electrodes 92, 93, 94, and 95. The current can be spread to the periphery through the extension portions e, which more improves current-spreading.

Hereinafter, various exemplary embodiments of the present disclosure will be described.

(1) A semiconductor light-emitting device including a plurality of branch electrodes located at different intervals. This prevents current concentration.

(2) A semiconductor light-emitting device including an electrode to which a plurality of wires can be bonded. This prevents current concentration even when a wire-bonding defect occurs on the electrode.

(3) A semiconductor light-emitting device including a first bonding electrode and a second bonding electrode supplying the current for recombination of electrons and holes, a first branch electrode and a second branch electrode extended from the first bonding electrode, and a third branch electrode extended from the second bonding electrode, disposed between the first branch electrode and the second branch electrode, and having a first interval from the first branch electrode and a second interval smaller than the first interval from the second branch electrode, wherein the second branch electrode is located farther from the center of the light-emitting device than the first branch electrode, the second branch electrode is located farther from the center of the light-emitting device than the third branch electrode, and at least one of the first bonding electrode and the second bonding electrode is disposed in a central portion of one side of the light-emitting device. This enables current-spreading from the central portion of the light-emitting device to the periphery.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

What is claimed is:

1. A semiconductor light-emitting device generating light by recombination of electrons and holes, the semiconductor light-emitting device comprising:
a first bonding electrode and a second bonding electrode supplying the current for the recombination of the electrons and holes;
a first branch electrode and a second branch electrode extended from the first bonding electrode; and
a third branch electrode extended from the second bonding electrode, located between the first branch electrode and the second branch electrode, and having a first interval from the first branch electrode and a second interval smaller than the first interval from the second branch electrode,
wherein the second branch electrode is located farther from the center of the light-emitting device than the first branch electrode, and the second branch electrode is located farther from the center of the light-emitting device than the third branch electrode.

2. The semiconductor light-emitting device of claim 1, wherein at least one of the first bonding electrode and the second bonding electrode comprises two bonding pads.

3. The semiconductor light-emitting device of claim 1, wherein at least one of the first bonding electrode and the second bonding electrode is positioned in a central portion of one side of the light-emitting device.

4. The semiconductor light-emitting device of claim 3, wherein the first bonding electrode and the second bonding electrode are positioned to face each other.

5. The semiconductor light-emitting device of claim 1, wherein the first branch electrode is extended toward the second bonding electrode.

6. The semiconductor light-emitting device of claim 1, comprising a fourth branch electrode extended from the second bonding electrode and located at a third interval smaller than the second interval from the second branch electrode.

7. The semiconductor light-emitting device of claim 2, wherein at least one of the first bonding electrode and the second bonding electrode is disposed in a central portion of one side of the light-emitting device; the first bonding electrode and the second bonding electrode are disposed to face each other; and the first branch electrode is extended toward the second bonding electrode.

8. The semiconductor light-emitting device of claim 7, comprising a fourth branch electrode extended from the second bonding electrode and located at a third interval smaller than the second interval from the second branch electrode.

9. The semiconductor light-emitting device of claim 8, wherein the light-emitting device is a III-nitride semiconductor light-emitting device.

10. A semiconductor light-emitting device generating light by recombination of electrons and holes, the semiconductor light-emitting device comprising:
a first bonding electrode and a second bonding electrode supplying the current for the recombination of the electrons and holes, at least one of the first bonding electrode and the second bonding electrode having two bonding pads;
a first branch electrode and a second branch electrode extended from the first bonding electrode; and
a third branch electrode extended from the second bonding electrode, disposed between the first branch electrode and the second branch electrode, and having a first interval from the first branch electrode and a second interval smaller than the first interval from the second branch electrode
